(19) United States
(12) Patent Application Publication
(10) Pub. No.: US 2026/0166586 A1
(43) Pub. Date: Jun. 18, 2026

(54) ADHESION PROMOTER, LAMINATE AND METHOD OF FORMING THE LAMINATE

(71) Applicant: CANON KABUSHIKI KAISHA, Tokyo (JP)

(72) Inventors: Fen WAN, Austin, TX (US); Weijun LIU, Cedar Park, TX (US); Amy R. KLOHN, Austin, TX (US)

(21) Appl. No.: 18/983,724

(22) Filed: Dec. 17, 2024

(51) Int. Cl. B05D 7/00; B05D 1/00; B05D 3/06

(52) U.S. Cl. CPC B05D 7/542; B05D 1/60; B05D 3/067; B05D 2210/00

(57) ABSTRACT

An adhesion promoter for adhering a curable composition to a substrate can comprise a first compound, the first compound including a vinyl silane; and a second compound, the second compound including a dipodal silane, wherein the dipodal silane does not contain a vinyl group. The adhesion promoter can be implemented in a laminate to provide excellent strength assistance of a resist coating layer to a substrate.

### FIELD OF THE DISCLOSURE

The present disclosure relates to an adhesion promoter and a laminate formed by using the adhesion promoter, wherein the adhesion promoter comprises a vinyl silane and a dipodal silane not including a vinyl group.

### BACKGROUND

UV-curable materials in the field of nanoimprint lithography (NIL) and inkjet adaptive planarization (IAP) can include vinylbenzene-based polymerizable materials for forming cured resist layers having a high etch resistance and high thermal stability. However, one disadvantage of such cured resist layers is a weak adhesion to the underlying substrate.

There exists a need to improve the adhesion strength of resist layers formed from curable vinylbenzene-based monomer compositions to the underlying substrate, particularly in the field of NIL and IAP processing.

### SUMMARY

In one embodiment, an adhesion promoter for adhering a curable composition to a substrate can comprise a first compound, the first compound including a vinyl silane; and a second compound, the second compound including a dipodal silane, wherein the dipodal silane may not contain a vinyl group.

In one aspect of the adhesion promoter, the vinyl silane of the first compound can have the structure of formula (1) or formula (2):

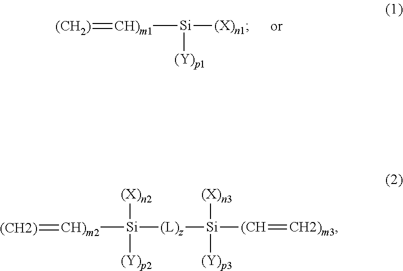

wherein X is OR, or SR, or NR₂, with R being C₁-C₃-alkyl; Y is C₁-C₃-alkyl;
L is C₁-C₃-alkyl, NH, or O, or S;
n₁ is 1, 2, or 3; m₁ is 1, 2, or 3; p₁ is 0, 1, or 2;
n₂, n₃, m₂, m₃: is 1, 2, or 3;
p₂, p₃: is 0 or 1;
z is 0 or 1; and

$${n}_{1} + {m}_{1} + {p}_{1} = 4 ; {n}_{2} + {m}_{2} + {p}_{2} = 3 ; {n}_{3} + {m}_{3} + {p}_{3} = 3 .$$

In another aspect of the adhesion promoter, the dipodal silane of the second compound can have the structure of formula (3):

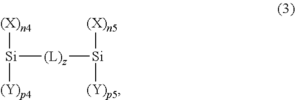

wherein X is OR, or SR, or NR₂, with R being C₁-C₃-alkyl; Y is C₁-C₃ alkyl; L is C₁-C₃-alkyl, NH, or O, or S; z is 0 or 1; and
n₄, n₅ is 1, 2, or 3; p₄, p₅ is 0, 1, or 2; n₄+p₄=3; n₅+p₅=3.

In a particular aspect, the dipodal silane of the second compound can include:

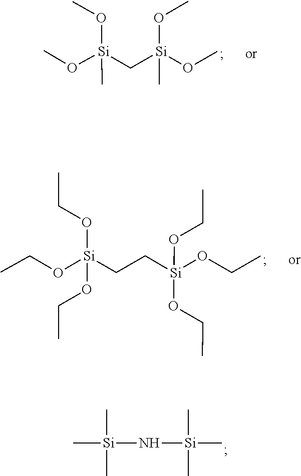

or any combination thereof.

In further particular aspects of the adhesion promoter, the vinyl silane of the first compound can include:

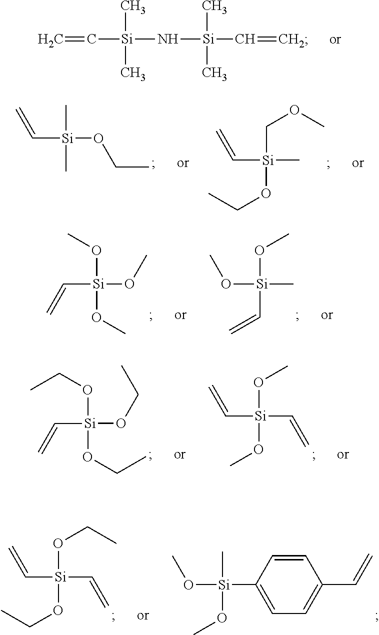

or any combination thereof.

In a certain particular aspect of the adhesion promoter, the vinyl silane of the first compound can include

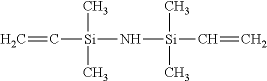

and the dipodal silane of the second compound include

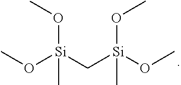

In one aspect of the adhesion promoter, the weight percent ratio of the first compound to the second compound can range from 1:1 to 10:1. In a particular aspect, the weight percent ratio of the first compound to the second can range from 3:1 to 8:1.

In a further aspect of the adhesion promoter for adhering a curable composition to a substrate, the curable composition can be configured for use in a nanoimprint lithography (NIL) process. In another aspect, the curable composition may be configured for use in an inkjet adaptive planarization (IAP) process.

In another embodiment, a laminate can comprise a substrate; an adhesion promoter layer directly overlying the substrate; and a coating layer directly overlying the adhesion promoter layer, wherein the adhesion promoter of the adhesion promoter layer comprises a first compound, the first compound including a vinyl silane; and a second compound, the second compound including a dipodal silane, wherein the dipodal silane does not contain a vinyl group.

In one aspect of the laminate, the material of the substrate can comprise silicon, aluminum, zirconium, tin, titanium, nickel, or any oxide thereof.

In a further aspect, the thickness of the adhesion promoter layer can be at least 0.5 nm and not greater than 100 nm.

In another aspect of the laminate, the weight percent ratio of the first compound to the second compound of the adhesion promoter layer can range from 1:1 to 10:1.

The yet another aspect of the laminate, the coating layer can be a cured layer of a curable composition, wherein the curable composition can comprise a polymerizable material, the polymerizable material including at least 80 wt % of a multi-functional vinylbenzene monomer based on the total weight of the polymerizable material.

In a further aspect, the coating layer of the laminate can have an adhesion strength to the substrate of at least 8 MPa.

In one embodiment, a method of manufacturing an article can comprise: applying an adhesion promoter on a substrate to form an adhesion promoter layer, wherein the adhesion promoter can comprise a first compound, the first compound including a vinyl silane, and a second compound, the second compound including a dipodal silane, the dipodal silane not containing a vinyl group; applying a layer of a curable composition overlying the adhesion promoter layer; bringing the curable composition into contact with a superstrate; irradiating the curable composition with light to form a cured layer; removing the superstrate from the cured layer to obtain a laminate; and manufacturing the article from the laminate.

In one aspect of the method, applying the adhesion promoter layer can comprise vapor depositing the adhesion promoter on the outer surface of the substrate.

In another aspect of the method, the curable composition can comprise a polymerizable material, the polymerizable material including at least 80 wt % of a multi-functional vinylbenzene monomer based on the total weight of the polymerizable material.

In a further aspect of the method, the vinyl silane of the first compound of the adhesion promoter can have a structure of formula (1) or formula (2):

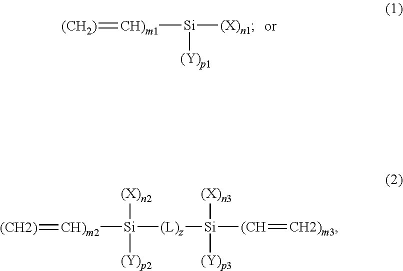

wherein X is OR, or SR, or NR2, with R being C₁-C₃-alkyl; Y is C₁-C₃-alkyl;
L is C₁-C₃-alkyl, NH, or O, or S;
n₁ is 1, 2, or 3; m₁ is 1, 2, or 3; p₁ is 0, 1, or 2;
n₂, n₃, m₂, m₃: is 1, 2, or 3;
p₂, p₃: is 0 or 1;
z is 0 or 1;

$${n}_{1} + {m}_{1} + {p}_{1} = 4 ; {n}_{2} + {m}_{2} + {p}_{2} = 3 ; {n}_{3} + {m}_{3} + {p}_{3} = 3 ;$$

and wherein the dipodal silane of the second compound of the adhesion promoter has a structure of formula (3):

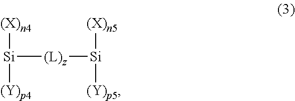

wherein X is OR, or SR, or NR₂, with R being C₁-C₃-alkyl; Y is C₁-C₃ alkyl;
L is C₁-C₃-alkyl, NH, or O, or S;
z is 0 or 1;
n₄, n₅ is 1, 2, or 3; p₄, p₅ is 0 or 1, or 2;

$${n}_{4} + {p}_{4} = 3 ; {n}_{5} + {p}_{5} = 3 .$$

### BRIEF DESCRIPTION OF THE DRAWINGS

Embodiments are illustrated by way of example and are not limited in the accompanying FIGURES.

FIG. 1A includes an illustration of a laminate according to one embodiment.

FIG. 1B includes an illustration of an assembly for testing the adhesion strength of the coating layer to the substrate of the laminate of FIG. 1A according to one embodiment.

Skilled artisans appreciate that elements in the figures are illustrated for simplicity and clarity and have not necessarily been drawn to scale. For example, the dimensions of some of the elements in the FIGURES may be exaggerated relative to other elements to help improve understanding of embodiments of the invention.

### DETAILED DESCRIPTION

The following description in combination with the FIGURES is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

As used herein, the terms “alkyl” group or “aryl” are used to encompass groups having no substituents (e.g., an unsubstituted alkyl group) but can also include substituted groups (e.g., a substituted alkyl group or a substituted aromatic ring).

In one embodiment, the present disclosure is directed to an adhesion promoter comprising the combination of a first compound and a second compound, wherein the first compound includes a vinyl silane, and the second compound includes a dipodal silane which does not contain a vinyl group.

It has been surprisingly found that the adhesion promoter of the present disclosure can provide excellent adhesion assistance between a polymeric coating layer and a substrate.

As used herein, the phrase “adhesion promoter” is interchangeable used for the above-described combination of the first compound including a vinyl silane and the second compound including a dipodal silane not containing vinyl groups, if not indicated otherwise.

As further used herein, the term “first compound” relates to the vinyl silane of the adhesion promoter, and the term “second compound” relates to the dipodal silane not including a vinyl group of the adhesion promoter.

Furthermore, as used herein, the term “laminate” is called interchangeable “coated substrate” or “multi-layer structure,” if not indicated otherwise.

In one aspect, the vinyl silane of the first compound can have a structure of formula (1) or formula (2):

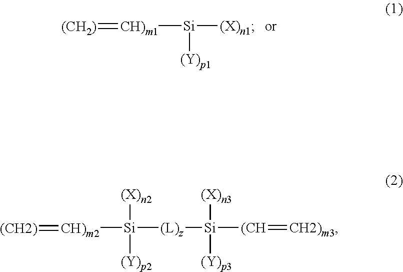

wherein
X is OR, or SR, or NR₂, with R being C₁-C₃-alkyl; Y is C₁-C₃-alkyl;
L is C₁-C₃-alkyl, NH, or O, or S;
n₁ is 1, 2, or 3; m₁ is 1, 2, or 3; p₁ is 0, 1, or 2;
n₂, n₃, m₂, m₃: is 1, 2, or 3;
p₂, p₃: is 0 or 1
z is 0 or 1;

$${n}_{1} + {m}_{1} + {p}_{1} = 4 ; {n}_{2} + {m}_{2} + {p}_{2} = 3 ; {n}_{3} + {m}_{3} + {p}_{3} = 3 .$$

Non-limiting examples of the vinyl silane of the first compound can be:

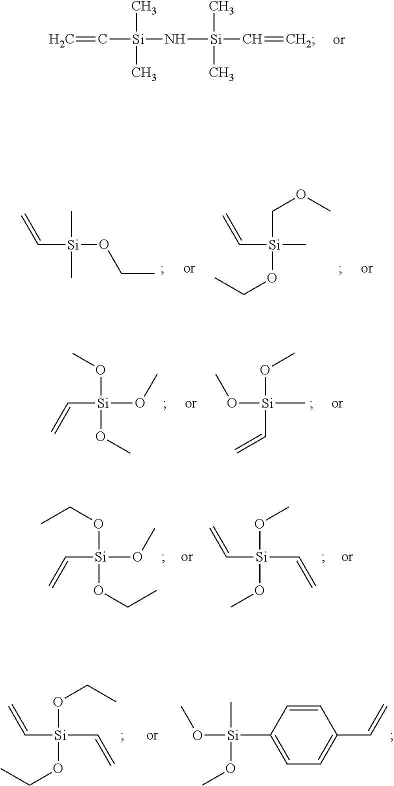

or any combination thereof.

The dipodal silane of the second compound differs from the vinyl silane of the first compound by not containing a vinyl group.

In one aspect, the dipodal silane of the second compound may further not contain an acrylate group.

In a particular aspect, the dipodal silane of the second compound may be free of the following functional groups: vinyl group, acrylate group, hydroxyl group, carboxyl group, primary amine, epoxy group and isocyanate group.

In one aspect, the dipodal silane of the second compound can have the structure of formula (3):

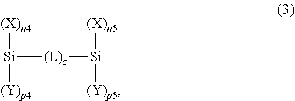

wherein X is OR, or SR, or NR₂, with R being C₁-C₃-alkyl; Y is C₁-C₃ alkyl;
L is C₁-C₃-alkyl, NH, or O, or S;
z is 0 or 1;
n₄, n₅ is 1, 2, or 3; p₄, p₅ is 0, 1, or 2; and

$${n}_{4} + {p}_{4} = 3 ; {n}_{5} + {p}_{5} = 3 .$$

In a certain aspect, the dipodal silane of the second compound can only include alkoxy-groups, or a combination of alkoxy groups and alkyl groups, while the linker between the two Si atoms can be C₁-C₃ alkyl or NH.

Non-limiting examples of the second compound falling under the structure of formula (3) can be:

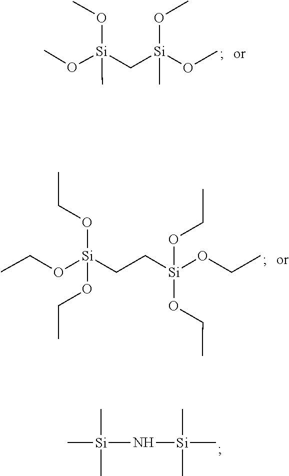

or any combination thereof.

In a certain particular aspect, the adhesion promoter of the present disclosure can include the combination of

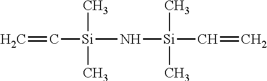

as the first compound, and

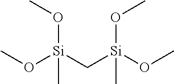

as dipodal silane of the second compound.

In one aspect, the weight percent ratio between the first compound and the second compound of the adhesion promoter can be at least 1:1, or at least 2:1, or at least 3:1, or at least 4:1, or at least 5:1. In another aspect, the weight percent ratio may be not greater than 15:1, or not greater than 12:1, or not greater than 10:1, or not greater than 8:1. The weight percent ratio can be a value between any of the numbers listed above, such as from 1:1 to 15:1, or from 2:1 to 10:1, or from 3:1 to 8:1.

In another aspect, the molecular weight of each of the first compound or the second compound of the adhesion promoter may be not greater than 600 g/mol, such as not greater than 500 g/mol, not greater than 450 g/mol, or not greater than 400 g/mol. In yet another aspect, the molecular weight may be at least 100 g/mol, or at least 120 g/mol, or at least 130 g/mol, or at least 150 g/mol, or at least 180 g/mol.

The adhesion promoter of the present disclosure is particularly suitable in the field of nanoimprint lithography (NIL) and inkjet adaptive planarization (IAP). It can have the advantage of improving the adhesion strength between an applied liquid photocurable resist after curing and an underlying substrate, for example, a silicon wafer.

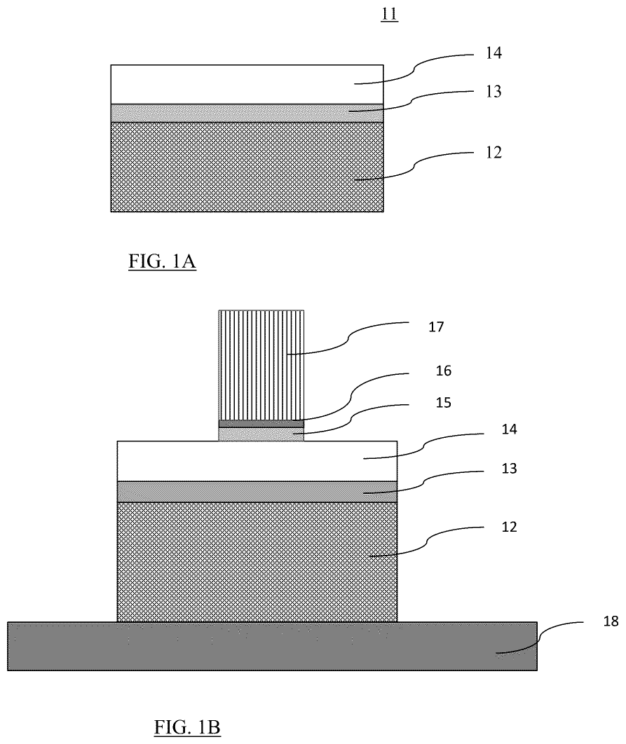

In one embodiment, as illustrated in FIG. 1A, the present disclosure is directed to a laminate (11) comprising a substrate (12), an adhesion promoter layer (13) directly overlying the substrate (12), and a coating layer (14) directly overlying the adhesion promoter layer (13). The adhesion promoter layer (13) can comprise the above-described adhesion promoter, i.e., the combination of the first compound including a vinyl silane, and the second compound including a dipodal silane and not containing a vinyl group.

In one aspect, the adhesion promoter layer (13) can form covalent bonds with the substrate (12) and covalent bonds with the coating layer (14). In a certain aspect, the vinyl groups of the vinyl silane of the first compound can form covalent bonds with the vinyl groups of vinyl monomers contained in the applied curable composition, which forms after curing the coating layer (14), while functional groups being present on the surface of the substrate, for example, hydroxyl groups, may react with other functional groups of the first compound and/or the second compound.

In one embodiment, a method of forming an article can comprise forming the above-described laminate (11) and further processing the laminate.

In one aspect, forming the laminate (11) can include: i) applying an adhesion promoter layer (13) directly overlying the substrate (12); and ii) applying a coating layer (14) directly overlying the adhesion promoter layer (13).

The substrate (12) of the laminate (11) can be a material selected from a metal, a metal alloy, a ceramic, a glass, or a polymer. In aspects, the substrate can comprise silicon, aluminum, zirconium, tin, titanium, or nickel, or their oxides. In a particular aspect, the substrate can be a silicon wafer. Not being bound to theory, functional groups contained in the outer surface region of the substrate can react by forming covalent bonds with functional groups of the adhesion promoter.

In one particular aspect, the adhesion promoter layer can be applied on the substrate by vapor deposition. Before the vapor deposition, the two compounds of the adhesion promoter can be combined and mixed together to form a solution.

In a certain aspect, the vinyl silane of the first compound can partially undergo self-cross-linking and/or crosslinking with the dipodal silane of the second compound during or after vapor deposition.

Vapor deposition can be conducted by using a bubbler, or a vaporizer, or manually. The bubbler and the vaporizer can use an inert gas, typically nitrogen, to cause the adhesion promoter to vaporize, and the vapor is blown into a closed chamber containing a substrate (e.g., a Si wafer) on which the adhesion promoter is deposited. After a certain given time, the wafer can have sufficient deposited adhesion promoter on its surface and may be used for IAP or NIL processing. In comparison to spin coating, the vaporization can be easily integrated into an automated IAP or NIL process, which can increase the throughput.

In the aspect of manual vaporization, a defined amount of the adhesion promoter can be added to an open container, e.g., a petri dish, and the open container with the adhesion promoter may be placed in a closed vessel, such as a desiccator or a Wafer Foup. The substrate (e.g., a silicon wafer) can be placed above to adhesion promoter at a defined distance. Depending on the vapor pressure of the adhesion promoter and the applied vacuum, the adhesion promoter will vaporize in the closed vessel in a defined period of time and deposit on the substrate.

In certain aspects the vapor pressure of each of the first and second compound of the adhesion promoter can be at least 0.01 Torr at 25° C., or at least 0.05 Torr, or at least 0.08 Torr, or at least 0.1 Torr, or at least 0.15 Torr, or at least 0.2 Torr, or at least 0.5 Torr, or at least 1 Torr, or at least 5 Torr, or at least 10 Torr. In another aspect, the vapor pressure of the first compound and the second compound may be not greater than 100 Torr at 25° C., or not greater than 80 Torr, or not greater than 50 Torr, or not greater than 30 Torr, or not greater than 20 Torr.

In another aspect, the vapor molar ratio Vi/Vj of the first compound and the second compound can be at least 1, or at least 2, or at least 4, or at least 7, or at least 10, or at least 20, or at least 30, or at least 50. In another aspect, the molar vapor ratio Vi/Vj may be not greater than 500, or not greater than 100, or not greater than 50, or not greater than 30. The vapor molar ratio can be a value between any of the listed numbers above, such as from 4 to 20, or from 5 to 15. As used herein, the vapor molar ratio Vi/Vj is defined as the quotient Vi/Vj=[(Wi/Mwj)*Vpi)/(Wj/Mwi)*Vpj), wherein Wi is the weight fraction of the first compound, Mwi is the molecular weight of the first compound and Vpi is the vapor pressure of the first compound, and Wj is the weight fraction of the second compound, Mwi is the molecular weight of the second compound, and Vpj is the vapor pressure of the second compound.

In another particular aspect, the adhesion promoter layer can be applied by immersing the substrate in a liquid adhesion promoter, or in a solution containing the adhesion promoter dissolved in a solvent, thereby allowing the adhesion promoter to be adsorbed on the substrate surface.

In other aspects, the adhesion promoter layer can also be applied on the substrate by spin-coating, spraying, or brushing.

In a further aspect, the thickness of the adhesion promoter layer can be at least 0.1 nm, such as at least 0.2 nm, at least 0.3 nm, or at least 0.5 nm, or at least 1 nm, or at least 2 nm, or at least 3 nm, or at least 5 nm. In another aspect, the thickness of the adhesion promoter layer can be not greater than 15 nm, such as not greater than 10 nm, or not greater than 5 nm. The thickness of the adhesion promoter layer can be a value between any of the minimum and maximum values noted above, such as from 0.4 nm to 15 nm, or from 0.2 nm to 5 nm.

In one aspect, the amount of the adhesion promoter in the adhesion promoter layer can be at least 50 wt % based on the total weight of the adhesion promoter layer, or at least 80 wt %, or at least 90 wt %, or at least 95 wt %, or at least 98 wt %, or at least 99 wt %, or at least 99.5 wt %, or at least 99.9 wt %. In a particular aspect, the adhesion promoter layer can consist essentially of the adhesion promoter, except for unavoidable impurities.

In one embodiment, the coating layer (14) can be a cured resist formed by curing a curable composition. As used herein, if not indicated otherwise, the term curable composition relates to the curable composition for forming the coating layer (14) of the laminate (11).

In one aspect, the curable composition can comprise a polymerizable material which may form a polymeric network if initiated to polymerization by light and/or heat.

In one aspect, the polymerizable material of the curable composition may include at least one multi-functional vinylbenzene monomer. As used herein, the term multi-functional vinylbenzene monomer of the polymerizable material relates to a polymerizable monomer comprising one or more benzene rings and at least two vinyl groups directly attached to the one or more benzene rings. In certain aspects, the multi-functional vinylbenzene monomer can comprise at least three vinyl groups or at least four vinyl groups. In a particular aspect, the multi-functional vinylbenzene monomer can comprise two benzene rings and three vinyl groups attached to the benzene rings. A non-limiting example of such monomer can be 3,4′,5-trivinyl-1,1′biphenyl (3VPH).

In a particular aspect, the polymerizable material of the curable composition can comprise at least 50 wt % of at least one multi-functional vinylbenzene monomer based on the total weight of the polymerizable material, or at least 60 wt %, or at least 80 wt %, or at least 85 wt %, or at least 95 wt %, or at least 98 wt %. In another aspect 100% of the polymerizable material can be at least one multi-functional vinylbenzene monomer, or not greater than 97 wt %, or not greater than 95 wt %, or not greater than 90 wt %.

In a certain aspect, the polymerizable material can comprise up to 20 wt % polymerizable monomers which are different than multi-functional vinylbenzene monomers based on the total weight of the polymerizable material, or at least 30 wt %, or at least 40 wt %.

In one aspect, the polymerizable material of the coating composition can comprise an acrylate monomer in an amount of at least 1 wt % to not greater than 40 wt %, or at least 2 wt % and not greater than 30 wt %, or at least 5 wt % and not greater than 20 wt %, or at least 1 wt % and not greater than 10 wt % based on the total weight of the polymerizable material. In a particular aspect, the polymerizable material of the curable coating composition can be essentially free of acrylate monomers. As used herein, essentially free of acrylate monomers means that the amount of acrylate monomers is not greater than 1 wt % based on the total weight of the polymerizable material.

In one aspect, the amount of polymerizable material contained in the curable composition can be at least 60 wt % based on the total weight of the curable composition, or at least 70 wt %, or at least 80 wt %, or at least 90 wt %, or at least 95 wt %. In another aspect, the amount of polymerizable material may be not greater than 99 wt %, or not greater than 96 wt %, or not greater than 92 wt % based on the total weight of the curable composition.

In a further aspect, the curable composition can contain a solvent which is not polymerizable and can be removed by drying before and/or during the polymerization. In another certain aspect, the curable composition can be essentially free of a solvent. As used herein, essentially free of a solvent means that an amount of the solvent in the curable composition is less than 5 wt % based on the total weight of the curable composition, or less than 3 wt %, or less than 1 wt %.

In another aspect, the curable composition can be essentially free of particles, for example pigment particles. As used herein, being essentially free of particles means that the photocurable composition contains not more than 50 particles per ml having a size of at least 200 nm, or not more than 50 particles per ml having a size of at least 150 nm, or not more than 50 particles per ml having a size of at least 100 nm, or not more than 50 particles per ml having a size of at least 50 nm, or not more than 50 particles having a size of at least 20 nm, or not more than 50 particles per ml having a size of at least 10 nm.

In one embodiment, the viscosity of the curable composition at 23° C. can be at least 1.0 mPa·s, at least 5 mPa·s, at least 10 mPa·s, at least 15 mPa·s, at least 20 mPa·s, or at least 30 mPa·s. In another embodiment, the viscosity may be not greater than 100 mPa·s, such as not greater than 70 mPa·s, not greater than 50 mPa·s, not greater than 40 mPa·s, or not greater than 30 mPa·s. The viscosity of the curable composition can be a value between any of the minimum and maximum values noted above. All viscosities recited herein are viscosities measured with the Brookfield method, using a Brookfield Viscometer LVDV-II+Pro at 200 rpm, with a spindle size #18 and a spin speed of 135 rpm.

In yet a further aspect, the curable composition of the resist can contain at least one additive. Non-limiting examples of an additive can be a surfactant, a dispersant, a stabilizer, a co-solvent, an initiator, an inhibitor, or any combination thereof.

In a particular embodiment, the coating layer of the laminate can be an imprint resist layer attached to a wafer substrate by the adhesion promoter layer and adapted for a nanolithographic process.

The contact angle of a liquid resist to the applied surface is an important parameter in nanoimprinting, since it affects the drop spreading of the IAP resist and the further performance during processing. As a general rule can be applied that the smaller the contact angle the faster the drop spreading, and the larger the contact angle the better the wettability. An indication about the spreading behavior of an IAP resist can be the water contact angle, because changes in the IAP contact angle often correspond with changes in the water contact angle.

In one aspect, the water contact angle to the adhesion promoter layer of the present disclosure can be not greater than 90 degrees, such as not greater than 85 degrees, or not greater than 80 degrees, or not greater than 75 degrees. In another aspect, the water contact angle may be at least 30 degrees, or at least 40 degrees, or at least 50 degrees, or at least 60 degrees.

In another embodiment, the thickness of the coating layer after curing can be at least 10 nm, or at least 50 nm, or at least 100 nm. In another aspect, the thickness of the coating layer may be not greater than 1000 nm, or not greater than 500 nm, or not greater than 100 nm, or not greater than 50 nm.

In one aspect, the adhesion strength (herein also called pull-off strength) of the coating layer to the substrate at 23° C. can be at least 8 Mpa, such as at least 10 MPa, or at least 11 MPa, or at least 12 MPa, or at least 13 MPa, of at least 14 MPa, or at least 15 MPa. In another aspect, the adhesion strength may be not greater than 30 MPa, or as not greater than 25 MPa, or not greater than 20 MPa.

In a particular embodiment, the curable composition can be applied on the substrate containing the adhesion promoter layer by ink-jetting. Depending on the material of the curable composition, curing can be conducted by UV radiation, heat treatment, or a combination thereof.

In one embodiment, the present disclosure is directed to a method of forming an article. The method can include: applying the above-described adhesion promoter on a substrate to form an adhesion promoter layer; applying a liquid imprint resist directly on top of the adhesion promoter layer; and bringing a superstrate in contact with the curable composition such that the curable composition forms a planar layer. Thereafter, the curable composition can be cured by radiation with light, for example, UV light, or via heat treatment, to form a cured planar layer. After curing of the curable composition, the superstrate can be removed from the cured layer, leaving a flattened resist on the substrate, which corresponds to the laminate. As further used herein, the term “planar layer” or “cured layer” are interchangeable used with the term “coating layer.” The laminate comprising the cured planar layer may be further processed to an article.

The cured layer (coating layer) can be used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, the adhesion promoter of the present disclosure can bind a coating layer to a substrate with an exceptionally high adhesion strength. It could be found that the adhesion performance of a vinyl silane can be largely increased if combined with a dipodal silane as a second compound, wherein the dipodal silane of the second compound does not contain vinyl groups. The two-compound adhesion promoter is particularly suitable for attaching a curable resist to a substrate in the field of IAP or NIL, wherein the curable resist comprises a high amount of multi-functional vinylbenzene monomers.

### EXAMPLES

The following non-limiting examples illustrate the concepts as described herein.

### Example 1

Forming of laminates using different adhesion promoters.

All formed laminates had the structure: substrate/adhesion promoter layer/coating layer (IAP resist), wherein the compounds of forming the adhesion promoter layer were varied.

As substrate was used a silicon wafer having a diameter of 12 inches and a thickness of 750 microns. The wafer was cut into four quarters, and one wafer quarter was placed within a small vacuum desiccator having a diameter of 150 mm (from Kimlet).

Before placing the silicon wafer quarter in the desiccator, 0.5 g of the adhesion promoter was placed at the bottom of the desiccator within a petri dish. Thereafter, the silicon wafer was placed at a distance of 50 mm above the petri dish in the desiccator, and the desiccator was closed with its lid. The silicon wafer was maintained for 1 hour within the desiccator at standard air pressure and room temperature (no vacuum was applied) to allow vapor deposition of the adhesion promoter on the silicon wafer.

As adhesion promoter representative for the present disclosure (sample S1) was used the combination of 80 wt % divinyltetramethyl-disilazane (VHMDS) and 20 wt % bis(methyl-dimethoxysilyl) methane. Before placing the adhesion promoter in the desiccator, the two compounds were combined in an 8-ml vial and mixed with a vortex mixture for one minute to obtain a uniform solution at room temperature. Thereafter, as described above, an amount of 0.5 g of the mixture was placed in the petri dish.

Comparative examples were conducted wherein the adhesion promoter was only a single compound, either falling under compound 1 or compound 2 of the adhesion promoter of the present disclosure, or a commercial acrylate-based adhesion promoter (see C5):

The following adhesion promoters for making comparative laminates were used:
100 wt % ethylenebis(triethoxysilane) (C1);
100 wt % bis(methyldimethoxysilyl) methane (C2);
100 wt % dimethoxymethylvinylsilane (C3);
100 wt % divinyltetramethyldisilazane (C4); and
100 wt % of acryloyloxymethyltrimethoxysilane (C5), an acrylate-based silane coupling agent for comparison. Although the adhesion promoter C5 does not fall under the first or second compound of the adhesion promoter of the present disclosure, it was used as a further comparison with a commercial adhesion promoter, and listed under the “first compound” in Table 1.

A summary of the structures of the adhesion promoters, grouped by first compound and second compound, for the representative examples S1 and the comparative examples C₁ to C₅ is shown in Table 1.

TABLE 1

| | Adhesion Promoter Structure/ | | Adhesion | Adhesion | Water |
|---|---|---|---|---|---|
| | Vapor Pressure at 25° C. | | strength | strength | Contact |
| | First Compound | Second Compound | [Lbf] | [MPa] | Angle[°] |
| S1 | 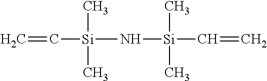 | 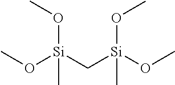 | 52.5 | 11.9 | 68.4 |
| | 2.16 Torr | 1.53 Torr | | | |
| C1 | | 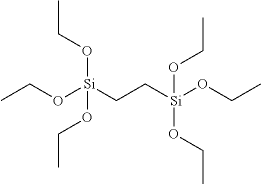 [SMILES: CCO[Si](CC[Si](OCC)(OCC)OCC)(OCC)OCC] | 1.12 | 0.25 | 2.9 |
| | | 0.342 Torr | | | |
| C2 | | 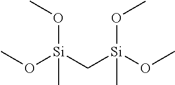 | 1.6 | 0.36 | 12.7 |
| | | 1.53 Torr | | | |
| C3 | 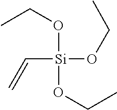 | | 14.6 | | 15.9 |
| | 3.09 Torr | | | | |
| C4 | 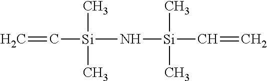 | | 29.6 | 6.7 | 72.1 |
| | 2.16 Torr | | | | |
| C5 | 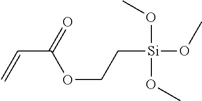 | | 32.3 | 7.3 | 49.5 |
| | 0.27 Torr | | | | |

After vapor depositing the adhesion promoter layer, the wafer was cut to a size of 2 inches×1 inch and a liquid photocurable resist composition, herein called IAP test resist, was applied on top of the adhesion promoter layer by dispensing with a pipette three drops of the IAP test resist, each drop having a volume of three microliters. The IAP test resist composition contained 100 parts of 3,5,3′-Vinyldiphenylmethane (TVPM), 1.5 parts photoinitiator Irgacure 1316, 4 parts photoinitiator Irgacure 651, and 3 parts surfactant SA3070 from Aoki Oil Industrial Co., Ltd.

Thereafter, on top of the dispensed IAP test resist was placed a glass slide coated with Cytop (from AGC Chemicals Americas, Inc.), wherein the Cytop coated side of the glass slide was facing the IAP test resist.

The IAP test resist contained in the stack was cured with UV radiation having a wavelength of 365 nm, using a total radiation energy of 30 mJ/cm² to form a solid IAP resist layer. After the curing and removing the glass slide, a laminate was obtained with the layer structure silicon wafer/adhesion promoter layer/IAP resist layer, wherein the thickness of the cured IAP resist layer was about 200 microns.

For the testing of the adhesion strength of the cured IAP resist layer to the silicon substrate, which is herein also called interchangeable pull-off strength, the force needed to pull-off the IAP layer (14) from the substrate (12) via an adhesively connected glass rod (17) was measured.

Specifically, as illustrated in FIG. 1B, the following setup for the adhesion test was prepared:

A glass rod (17) (Technical Glass Products, WE 214 fused quartz rod) having the size of 5 mm diameter×12 mm length was adhesively attached to the IAP layer (14) of the laminate (11). For attaching the glass rod to the IPA layer, the glass rod was coated on one end with an adhesion primer (herein called also just primer) using a cotton swab and baked at a temperature of 180° C. to obtain a firm adhesion between the primer and the rod. The adhesion primer contained 81 g IsoRad 501 (an aromatic polyacrylate from Schenectady International, Inc. in Schenectady, New York), 18 g Cymel 303ULF (comprising as a main ingredient hexamethoxymethyl-melamine (HMMM)), and 1 g of a catalyst (Cycat 4040). Thereafter, the primer coated end of the glass rod (16) was adhesively attached to the laminate by coating it with a NIL resist, and placing the rod with the NIL-resist coated end (15) at the center of the cured outer IAP layer (14) of the laminate (11). The NIL resist was cured with UV radiation of 365 nm and a light intensity of 290 mW/cm² for 10 minutes, which caused the glass rod to be adhesively attached to the laminate. The NIL resist was selected to ensure that the adhesive strength of the glass rod (17) to the IAP layer (14) via the cured NIL (15) was greater than the adhesive strength of the IAP layer (14) to the silicon wafer (12) via the adhesion promoter layer (13). The exact composition of the NIL resist was: 10 wt % isobornyl acrylate, 35 wt % benzyl acrylate, 50 wt % neopentyl glycol diacrylate; 3 wt % Darocur 4265 (from BASF); and 2 wt % TPO (from BASF).

Thereafter, the laminate containing the attached glass rod was glued with the backside (silicon wafer side) to an aluminum plate (18) having a size of (1 inch×25 inches×⅛ inch) using an epoxy adhesive (Gorilla Epoxy Adhesive Clear from Gorilla Glue Company). The epoxy adhesive was selected to ensure that the adhesion strength of the aluminum plate to the silicon wafer was stronger than the adhesion strength of the photo-cured resist layer to the silicon wafer.

The actual adhesion test (measuring the pull-off strength) was conducted by measuring the force needed to pull-off the IAP layer (14) from the substrate via the adhesively attached glass rod (17), using an Instron Model 5542 Tensile Tester.

For the testing, the above-described laminate attached to the aluminum plate (18) via the silicon wafer (12) and containing the glass rod (17) anchored with one end to the IAP layer (14) of the laminate via the photo-cured NIL resist (15) was placed in a fixed position in the Tensile Tester. A moving head from the Instron tensile tester was adjusted that it moved at a speed of 0.5 mm per minute towards the glass rod and hit the glass rod at its side, at a position 5.3-5.4 mm away from the end of the glass rod attached to the resist. The force was recorded at which the glass rod with the attached IAP resist layer (14) was separated from the silicon substrate (12). The adhesion strength (i.e., pull-off strength of the IAP resist to the silicon wafer) was measured in pounds per force (lbf) and normalized to lbf/mm² by dividing by the surface area of 19.62 mm² of the glass rod end. The normalized lbf/mm² value was further converted to the unit MPa by multiplication with the factor 4.4482. An illustration of the layered assembly containing the laminate of FIG. 1A is shown in FIG. 1B.

For each sample, the testing was repeated eight times, and an average value of the pull-off-strength was calculated.

The results of the adhesive strength measurements are also summarized in Table 1. It can be seen that the highest adhesion strength of 11.9 MPa was obtained when using as adhesion promoter the combination of 80 wt % divinyltetramethyldisilazane and 20 wt % bis(methyl-dimethoxysilyl) methane (sample S1). In contrast, all laminates formed by using only one compound, either falling under the first compound (C3 and C4) or the second compound (C1 and C2) had a much lower adhesion strength of the coating layer to the substrate. While the adhesion strength for comparative samples C3 and C4 was about 40% lower in comparison to sample S1, the adhesion strength of comparatives samples C1 and C2 was nearly not measurable. Furthermore, also the commercial acrylate-based adhesion promoter (C5) was inferior in comparison to sample S1. The results of the adhesion testing indicate that the dipodal silane of second compound by itself is not suitable as adhesion promoter, but can greatly assist by increasing the adhesion strength of the vinyl silane of the first compound.

### Example 2

Laminates have been formed and tested as described in Example 1, except that the adhesion promoter used for sample S1 was modified by using different ratios of compound 1 to compound 2.

While the laminate of sample S1 was formed with the adhesion promoter having a ratio of first compound to second compound of 4:1, this ratio was varied from 2.3:1 to 9:1, see samples S2, S3, and S4, summarized in Table 2.

The results show that the highest adhesion strength was obtained at a ratio of 5.7 to 1, while a further increase of the ratio caused a minor decrease in the adhesion strength. The data further indicate that in order to obtain an excellent adhesion strength of 10 MPa or greater the weight percent ratio of the first compound to second compound should be at least 3:1.

TABLE 2

| | Ratio of first | Vapor | Adhesion | Adhesion | Water |
|---|---|---|---|---|---|
| | compound to | molar | strength | strength | Contact |
| | second compound | ratio | [Lbf] | [MPa] | Angles[°] |
| S2 | 2.3:1 | 4 | 41.5 | 9.4 | 72.7 |
| | (7:3) | | | | |
| S1 | 4:1 | 7 | 52.5 | 11.9 | 68.4 |
| | (8:2) | | | | |
| S3 | 5.7:1 | 10 | 66.7 | 15.1 | 77 |
| | (8.5:1) | | | | |
| S4 | 9:1 | 15 | 56.3 | 12.8 | 76.1 |

### Water Contact Angle to Adhesion Promoter Layer.

The water contact angles to the applied adhesion promoter layers after vapor deposition were measured with a Drop Master DM-701 contact angle meter made by Kyowa Interface Science Co. Ltd. (Japan).

For the testing, 2 ml of distilled water was added to the syringe, of which 2 μl sample per test was added by the machine to the surface of the silicon wafer coated with the adhesion promoter layer. Drop images were continuously captured by a CCD camera from the time the resist drop touched the layer surface. The contact angle was automatically calculated by the software based on the analysis of the images. The water contact angles presented in Tables 1 and 2 are the contact angles at a time of 3 seconds after the IAP resist drop was touching the surface of the adhesion promoter layer.

A summary of the measured water contact angles to the applied adhesion layers is shown in Tables 1 and 2 as well. The water contact angles of representative samples S1 to S4 are all in the range between about 60 and 80 degrees, which indicates a good spreading behavior assumed an IAP resist would be applied. In contrast, the low water contact angles of comparative samples C1 and C2, next to the very low adhesion strengths of the IAP resist layers to the substrate, indicate that the dipodal silane alone of the second compound is not a suitable adhesion promoter. It was very surprising, however, that adding the dipodal silane of the second compound to the vinyl silane of the first compound could achieve a remarkable increase in the adhesion strength of the applied and cured IAP resist layer.

### Example 3

The same laminate was prepared as described for sample S1 in Example 1, except that the vapor deposition time was lowered from 1 hour to 30 minutes.

It could be shown that by lowering the vapor deposition time by 50 percent, the decrease in the adhesion strength was rather minor, from 11.9 MPa to 10.8 MPa. This indicates that only low amounts of vapor deposited adhesion promoter are needed to obtain a desired adhesion strength. Not being bound to theory, it is assumed that only a single or double layer of molecules of the adhesion promoter is required to create a highly efficient adhesion promoter layer.

TABLE 4

| | Vapor | | |
|---|---|---|---|
| | Deposition | Adhesion | Adhesion |
| | Time | strength | strength |
| Sample | [minutes] | [Lbs] | [MPa] |
| S1 | 60 | 52.5 | 11.9 |
| S1 | 30 | 47.6 | 10.8 |

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An adhesion promoter for adhering a curable composition to a substrate, the adhesion promoter comprising:
a first compound, the first compound including a vinyl silane; and
a second compound, the second compound including a dipodal silane, wherein the dipodal silane does not contain a vinyl group.

2. The adhesion promoter of claim 1, wherein the vinyl silane of the first compound has a structure of formula (1) or formula (2): 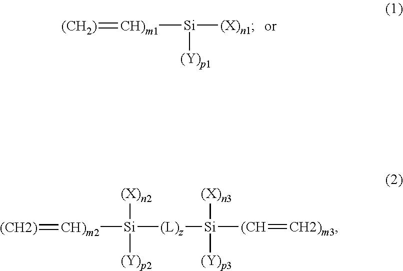
wherein X is OR, or SR, or NR₂, with R being C₁-C₃-alkyl; Y is C₁-C₃-alkyl;
L is C₁-C₃-alkyl, NH, or O, or S;
n₁ is 1, 2, or 3; m₁ is 1, 2, or 3; p₁ is 0, 1, or 2;
n₂, n₃, m₂, m₃: is 1, 2, or 3;
p₂, p₃: is 0 or 1
z is 0 or 1;
$${n}_{1} + {m}_{1} + {p}_{1} = 4 ; {n}_{2} + {m}_{2} + {p}_{2} = 3 ; {n}_{3} + {m}_{3} + {p}_{3} = 3 .$$

3. The adhesion promoter of claim 2, wherein the dipodal silane of the second compound has a structure of formula (3): 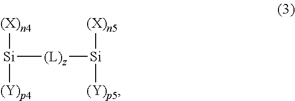
wherein X is OR, or SR, or NR₂, with R being C₁-C₃-alkyl; Y is C₁-C₃ alkyl;
L is C₁-C₃-alkyl, NH, or O, or S;
z is 0 or 1;
n₄, n₅ is 1, 2, or 3; p₄, p₅ is 0 or 1, or 2;
$${n}_{4} + {p}_{4} = 3 ; {n}_{5} + {p}_{5} = 3 .$$

4. The adhesion promoter of claim 3, wherein
the dipodal silane of the second compound includes: 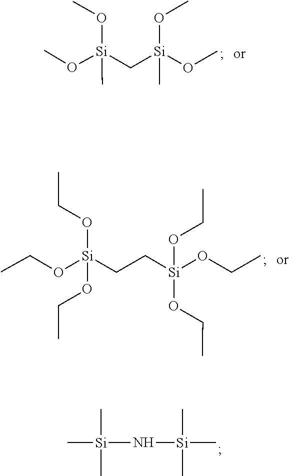
or any combination thereof.

5. The adhesion promoter of claim 2, wherein the vinyl silane of the first compound includes: 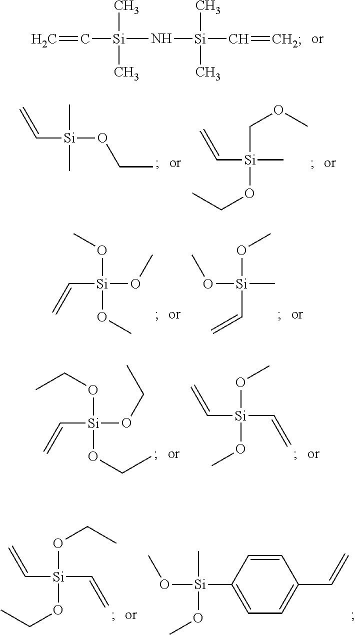
or any combination thereof.

6. The adhesion promoter of claim 5, wherein the vinyl silane of the first compound includes 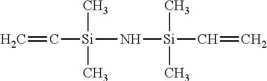
and the dipodal silane of the second compound includes

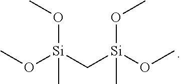

7. The adhesion promoter of claim 1, wherein a weight percent ratio of the first compound to the second compound ranges from 1:1 to 100:1.

8. The adhesion promoter of claim 7, wherein the weight percent ratio of the first compound to the second ranges from 2:1 to 10:1.

9. The adhesion promoter of claim 1, wherein the curable composition is configured for use in a nanoimprint lithography (NIL) process.

10. The adhesion promoter of claim 1, wherein the curable composition is configured for use in an inkjet adaptive planarization process.

11. A laminate comprising:
a substrate;
an adhesion promoter layer directly overlying the substrate; and
a coating layer directly overlying the adhesion promoter layer,
wherein an adhesion promoter of the adhesion promoter layer comprises
a first compound, the first compound including a vinyl silane; and
a second compound, the second compound including a dipodal silane,
wherein the dipodal silane does not contain a vinyl group.

12. The laminate of claim 11, wherein a material of the substrate comprises silicon, aluminum, zirconium, tin, titanium, nickel, or any oxide thereof.

13. The laminate of claim 11, wherein a thickness of the adhesion promoter layer is at least 0.5 nm and not greater than 100 nm.

14. The laminate of claim 11, wherein a weight percent ratio of the first compound to the second compound of the adhesion promoter layer ranges from 1:1 to 10:1.

15. The laminate of claim 12, wherein the coating layer is a cured layer of a curable composition, and wherein the curable composition comprises a polymerizable material, the polymerizable material including at least 80 wt % of a multi-functional vinylbenzene monomer based on the total weight of the polymerizable material.

16. The laminate of claim 11, wherein the coating layer has an adhesion force to the substrate of at least 8.0 MPa.

17. A method of manufacturing an article, comprising:
applying an adhesion promoter on a substrate to form an adhesion promoter layer, wherein the adhesion promoter comprises a first compound, the first compound including a vinyl silane, and a second compound, the second compound including a dipodal silane, the dipodal silane not containing a vinyl group applying a layer of a curable composition overlying the adhesion promoter layer;
bringing the curable composition into contact with a superstrate;
irradiating the curable composition with light to form a cured layer;
removing the superstrate from the cured layer to obtain a laminate; and
manufacturing the article from the laminate.

18. The method of claim 17, wherein applying the adhesion promoter layer comprises vapor depositing the first compound and the second compound of the adhesion promoter on the outer surface of the substrate.

19. The method of claim 17, wherein the curable composition comprises a polymerizable material, the polymerizable material including at least 80 wt % of a multi-functional vinylbenzene monomer based on the total weight of the polymerizable material.

20. The method of claim 17, wherein the vinyl silane of the first compound of the adhesion promoter has a structure of formula (1) or formula (2): 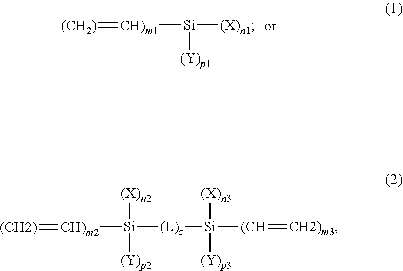
wherein X is OR, or SR, or NR₂, with R being C₁-C₃-alkyl; Y is C₁-C₃-alkyl;
L is C₁-C₃-alkyl, NH, or O, or S;
n₁ is 1, 2, or 3; m₁ is 1, 2, or 3; p₁ is 0, 1, or 2;
n₂, n₃, m₂, m₃: is 1, 2, or 3;
p₂, p₃: is 0 or 1
z is 0 or 1;
$${n}_{1} + {m}_{1} + {p}_{1} = 4 ; {n}_{2} + {m}_{2} + {p}_{2} = 3 ; {n}_{3} + {m}_{3} + {p}_{3} = 3 ;$$
and wherein the dipodal silane of the second compound of the adhesion promoter has a structure of formula (3): 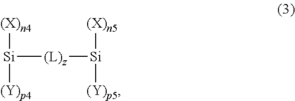
wherein X is OR, or SR, or NR₂, with R being C₁-C₃-alkyl; Y is C₁-C₃ alkyl;
L is C₁-C₃-alkyl, NH, or O, or S;
z is 0 or 1;
n₄, n₅ is 1, 2, or 3; p₄, p₅ is 0 or 1, or 2;
$${n}_{4} + {p}_{4} = 3 ; {n}_{5} + {p}_{5} = 3 .$$
